(19) United States
(12) Patent Application Publication
(10) Pub. No.: US 2002/0152440 A1
(43) Pub. Date: Oct. 17, 2002

(54) Apparatus and method for improving the quality of video communication over a packet-based network

(76) Inventors: Ilan Yona, Tel Aviv (IL); Moshe Elbaz, Kiriat Bialik (IL)

Correspondence Address: CARR & FERRELL LLP, 2225 EAST BAYSHORE ROAD, SUITE 200, PALO ALTO, CA, 94303, US

(21) Appl. No.: 10/045,125

(22) Filed: Oct. 26, 2001

Related U.S. Application Data
(60) Provisional application No. 60/243,886, filed on Oct. 27, 2000.

(51) Int. Cl. G08C 25/00; H03M 13/00; G06F 11/30; G06F 11/00; H04L 1/00; H04L 12/56; H04L 12/28

(52) U.S. Cl. 714/746; 370/394

(57) ABSTRACT

A network interface unit is provided with a missing packets repair logical unit, which repairs real time video transmissions by replacing the missing packets. The missing packets repair unit detects and replaces missing packets in a received video stream. The missing packets can be detected by finding packets that are out of sequence.

### BACKGROUND

1. Field of the Invention

The field of the invention is generally video communication and more specifically improved video communication quality over a packet-based network such as an Ethernet or Internet Protocol (IP) using H.323 protocol or similar standard.

2. Background Art

Conventionally, a packet-based network such as an Ethernet or IP does not offer an end-to-end connection with a guarantee that all packets will reach their destination. Therefore communication over a packet-based network using different technologies is necessary to overcome packet loss. For example, communication that is not performed in real time, such as e-mail, uses protocols such as Transmission Control Protocol (TCP), which is a handshake protocol that verifies the arrival of all packets. If a packet is not received, a request is made for a retransmission of the lost packet. Alternatively, other protocols, such as User Datagram Protocol (UDP)/IP, typically send a notification about the problem of the packet loss and then handle the lost packet separately.

Video communications are performed in real time. However, any delay between endpoints (a physical location or apparatus that can generate and/or terminate information streams) reduces the quality of the communication performed in real time. Furthermore, a handshake protocol such as TCP/IP increases the delay, which is the time interval between the action of one side and the response of the other side. The increased delay damages the flow of a conversation. Consequently, TCP/IP is a difficult protocol to use for real time communications.

Therefore, video communications use UDP/IP with H.323, Session Initiation Protocol (SIP), or similar standards instead of using TCP/IP. UDP/IP is used primarily for broadcasting video streams over a network and it is a connectionless protocol, which runs on top of IP networks. Unlike TCP/IP, UDP/IP has very few error recovery services. Instead UDP/IP sends and receives datagrams over an IP network directly. Since UDP/IP does not have a feedback mechanism the packets that do not reach their destination will be lost. The percentage of packets lost during transmission is typically up to about 10%.

Conventional video communications use compression standards such as H.261, H.263 and Moving Pictures Experts Group (MPEG). These video compression standards typically have two types of frames: the “Intra” frame, which is a non-referential image, and the “Non intra” frame, which is a referential frame, similar to but not limited to frames such as Inter frame (P frame), B frame, and PB frame. Video compression standards use the difference between the current “Non Intra” frame and a previous frame for compression, regardless whether the previous frame was an Intra or “Non Intra” frame.

A video packet includes video parts, which may be a whole frame or part of a frame. Each frame may include one or more parts, where a part of a frame may include, for example, a few Groups Of Blocks (GOB), part of a GOB, Slice, part of a Slice or a few Macro Blocks (MBs). More information about said GOBs, Slices and MBs can be found in standards H.261, H.263, MPEG, etc.

Since video compression (i.e., encoding/decoding) is based on referential information, “Non Intra” frames, the loss of a packet may damage video quality for all later frames until a new Intra frame arrives. The loss of the packet may also cause loss of video synchronization. Typically, a video decoder of an endpoint handles lost packets by requesting transmission of an Intra frame so that the referential information of the Infra frame can be used to correct the synchronization and be the basis for calculating the referential frames that follow. This request for transmission can be performed by using a Video Update Picture Indication (VUPI) request.

A Multipoint Control Unit (MCU) is a node on a network, which provides the capability for two or more terminals to participate in a multimedia communication session. Therefore, the MCU may transfer a received data stream with missing packets, to multiple participants' endpoints. Thus the use of MCUs may create a bigger problem than just a lost packet in an endpoint-to-endpoint direct connection, because the lost packet will be missing to multiple endpoints rather than just one endpoint. There are few known ways by which an MCU handles missing packets; none of which replace the missing packets. For example, the MCU may send video source packets while ignoring the missing packets, and let the endpoints make a VUPI request. In a videoconference with more than two endpoints, several participants may simultaneously receive communications from one source, such as a conference speaker. If a packet is lost during transmission from the video source (the conference speaker) to the MCU, each of the participants would request a VUPI from the MCU. However, the numerous VUPI requests and the INTRA frames that the follow VUPI requests could overwhelm the network, especially if there is a high packet loss rate. Further, during Internet communications each participant may experience packet loss at a different time, and will therefore request a VUPI at different times, thereby overwhelming the network with sporadic transmissions of Intra frames. Since Intra frames are approximately 10 times “bigger” than “non Intra” frames, transmission of Intra frames may cause frame rate derogation and reduces the video quality of the conference.

Therefore, there is a need for a system and method for improving video communications quality over a packet-based network.

### SUMMARY OF THE INVENTION

The present invention provides a novel method and apparatus for repairing video stream errors such as missing packets of an incoming compressed video stream. The system identifies a missing part or unit of a video stream (e.g., a lost packet) by tracking a sequence number associated with each packet. An analysis is then performed to determine which sub-units (e.g. GOBs, Slices, and/or MBs) are absent from the video stream, and to create one or more substitute video stream parts (i.e. repair packets) to compensate for absent sub-units. In an exemplary embodiment the repair packets include the minimum required video bits to keep the stream or flow of the video stream synchronized. This minimum bit requirement means that none of the MacroBlocks' (MBs') video data is placed or reconstructed in the packet. Instead, a decoder treats a repaired video stream part, such as a GOB, as an uncoded part that represents the same information as in the previous frame. The repaired information is then transferred to its destination and replaces the original information.

Additionally, the MCU may ask for an “update request” from the video source, which may include a VUPI request. When compression standard allows, only a part of a picture that includes the missing sub-units (such as MBs) is requested. An example of a compression standard that allows for the request of a partial picture is H.263.

Replacement of the missing parts provides for continuity of the video stream at a receiver site. This continuity enables smooth parsing, without synchronization losses and prevents re-synchronization process by the video “decoders.” The decoder, among other places, may be located inside the MCU, or outside of the MCU at the participant's endpoint.

Alternatively, if the missing part belongs to a nonreferential image (e.g., an Intra frame), then the video stream is not corrected. Instead a new nonreferential image (such as Intra frame) is requested.

### BRIEF DESCRIPTION OF THE DRAWINGS

The invention will be more readily understood from reading the following specification and by reference to the accompany drawings showing an example of the invention.

FIG. 1 is a block diagram of a prior art network interface unit;

FIG. 2 is a block diagram of an exemplary embodiment of the present invention; and

FIG. 3 is a flow diagram of the steps of an exemplary embodiment of the present invention.

### DETAIL DESCRIPTION OF THE INVENTION

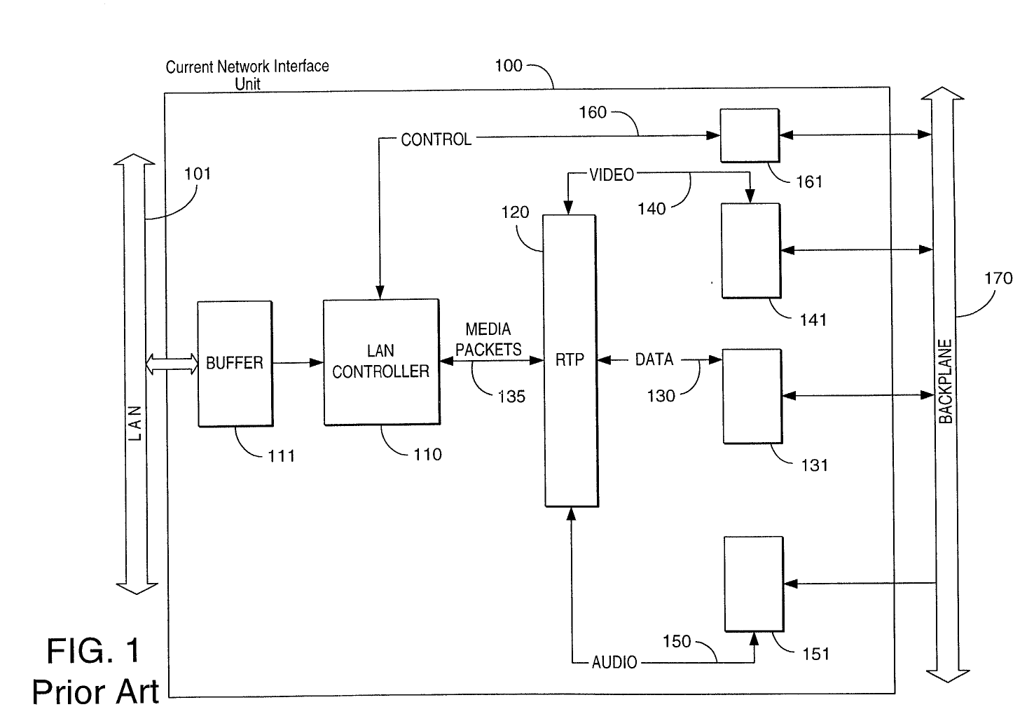

FIG. 1 is a block diagram of a prior art network interface unit 100. As shown, a Local Area Network (LAN) controller 110 grabs required multimedia packets from a LAN 101 via a buffer 111. Preferably, the LAN controller 110 then sorts the multimedia packets into two types of streams: control streams 160 and media streams 135. The control stream 160 is transferred via buffers 161 to a backplane 170.

The media streams 135 are transferred to a Real Time Transfer Protocol (RTP) unit 120, a packetizing/depacketizing unit that sorts the streams into Audio streams Video streams 140 and Data streams 130 and transfers them via buffers 141, 151 and 131, respectively, to the backplane 170. More specifically, video streams 140 are transferred through buffer 141 to the backplane 170 without repairing the missing packets, while audio streams 150 are transferred via buffer 151.

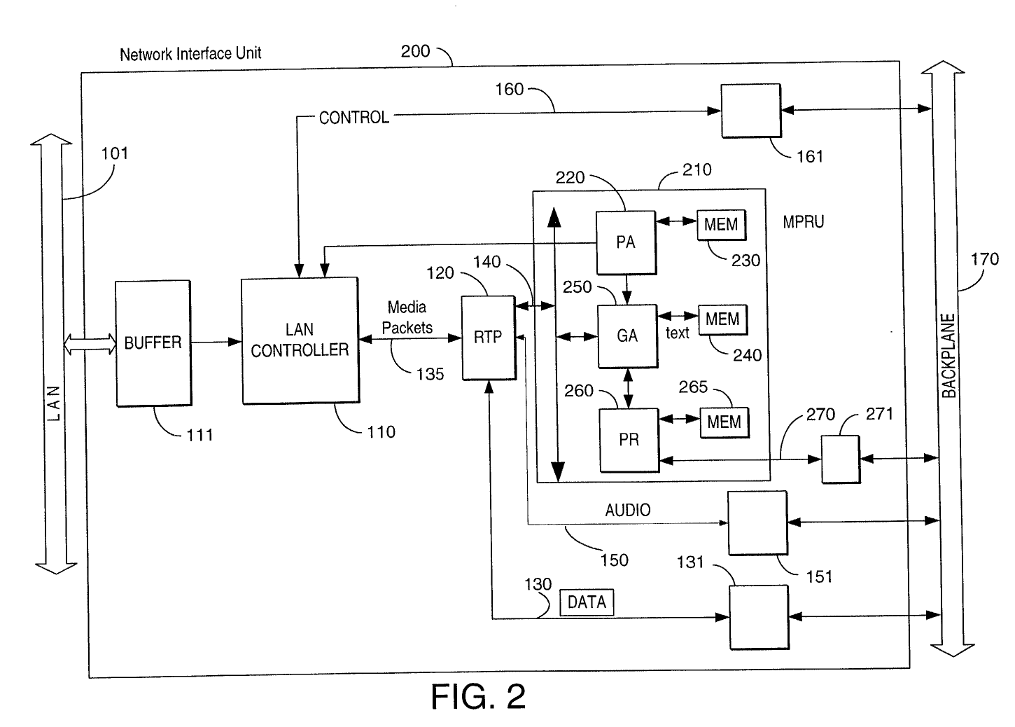

Conversely, FIG. 2 is a block diagram illustrating an exemplary embodiment of a network interface unit 200 according to the present invention. Preferably, the network interface logical unit 200 includes a LAN controller 110, RTP unit 120, Video streams 140, Missing Packets Repair logical Unit (MPRU) 210, Packet Analyzer logical unit (PA) 220, memory 230, GOB history memory 240, GOB Analyzer logical unit (GA) 250, Packet Repair logical unit (PR) 260, and Temporary Packets Memory (TPM) 265.

It should be noted that the term “GOB” represents a “Slice” for situations where slices are used instead of GOBs. In such a case, the GOB ID Number is replaced by the Slice ID, which is the MBA field in the Slice header. The MBA indicates the first MB in the Slice.

The network interface logical unit 200 is similar to network interface unit 100 (FIG. 1) in that they both include a LAN controller 110 and RTP unit 120. However, in contrast to the prior art device of network interface 100, the FIG. 2 system also includes a Missing Packets Repair logical Unit (MPRU) 210.

Operationally, video streams 140 from the RTP 120 are transferred to the MPRU 210. Inside the MPRU 210 the video stream 140 is distributed to three logical units: PA 220, GA 250, and PR 260. The PA 220 reads a current packet sequence number of a received packet, compares the current sequence number to the expected sequence number, and in case of mismatch sends indications of packet loss to the LAN controller 110, GA 250, and PR 260. The expected sequence number is based on the history of the received packets stored in its memory 230.

The GA 250 analyzes which GOBs/Slices are associated with each received packet and stores this information in the GOB history memory 240. The analyzing can be done by parsing the video stream of a packet and/or by grabbing the information regarding the GOB/Slice ID from the RTP header. This information about the GOB/Slice header in the RTP Header does not always exist and is based on the RFC.

When the GA 250 receives an indication that there are missing packets prior to the current packet, GA 250 uses the last stored information in the memory 240 and the first GOB/Slice ID Number that was found in the current packet to analyze which GOBs/MBs are missing. The GA 250 then sends this information to the PR 260, which in turn receives the incoming video stream 140 of packets and stores them in the Temporary Packet Memory (TPM) 265. Thus, the TPM 265 receives both indications about a missing packet from the PA 220 and the identification numbers of the corresponding missing GOB/MBs from the GA 250. If there are no missing packets, the PR 260 reads the last stored packet from the TPM 265 and sends the stored packet, as is, via buffer 271 to the backplane 170. When the PR 260 receives the indications from the PA 220 and from GA 250, the PR 260 creates repaired packets and sends the corrected stream, including the repaired packets with the stored packets from the TPM 265 via buffer 271 to the backplane 170. The determination of which GOBs/MBs are missing is based on the compression standard as explained below by example.

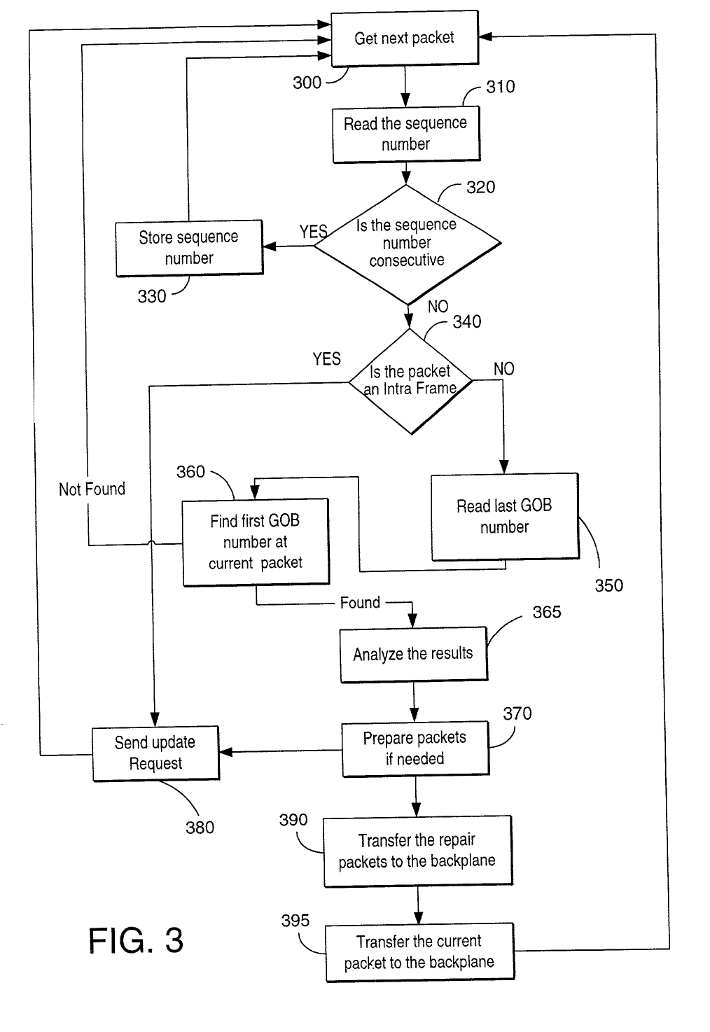

FIG. 3 is a flow diagram illustrating steps of an exemplary method for repairing missing packets according to the present invention. Initially, the MPRU 210 (FIG. 2) receives a next packet in step 300. The PA 220 (FIG. 2) then reads the sequence number of the packet in step 310 and compares the sequence number of the packet to the sequence number of the previous packet stored in the memory 230 (FIG. 2). Subsequently, the PA 220 (FIG. 2) checks if the packet is consecutive in decision box 320 based on the comparison of the sequence numbers. If the packets are consecutive, the PA 220 stores the current packet's sequence number in the memory 230 and returns to step 300 to receive a new packet. However, if the packets are not consecutive, meaning that one or more packets have been lost, then PA 220 checks if the missing packet belongs to an Intra frame or “Non Intra” frame in step 340.

One way of keeping track of the type of frame is to sample the indication of frame type. For example, the PA 220 may check the frame type by reading a “frame's header,” GOB “0” of the last packet. In H.263, the frame header is part of a header of GOB “0” while in H.261 the frame header is identified by GOB ID Number “0”.

If the missing packet is part of Intra frame 340, no packet repair is necessary and a VUPI request is performed in step 380 and the process returns to step 300 to receive the next packet. If the packet contains part of a “Non Intra” frame the PA 220 sends a missing packets acknowledgement to the GA 250 (FIG. 2) and the PR 260 (FIG. 2). The GA 250 in step 350 uses the information stored in the memory 240 (FIG. 2) to get the last GOB ID Number that arrived before the missing packets. For example, if the last GOB before the missing packet is GOB (j), then the GA 250 finds the first GOB in the current packet in step 360, e.g., GOB (k). Based on these two GOB ID Numbers (i.e., (j) and (k)), the compression standard, and the source format (e.g., Common Intermediate Format (CIF), 4 CIF, or Quarter CIF (QCIF)), the GA 250 determines in step 365 which are the missing GOBs.

In the case that the compression stream is using Slices instead of GOBs, the GA 250 analyzes and stores the last Slice ID, which is the MBA field in the Slice header of the last received packet. Then the GA finds the Slice ID of the first Slice. By using this two MBAs and the width of the Slice the GA 250 analyzes which MBs are the missing.

The following are a few examples of the analysis, for video algorithms H.261 and H.263 and two sources formats CIF and QCIF. The numbers in the following table specify the sequence of GOB ID Numbers used in those cases.

| | QCIF | CIF |
|---|---|---|
| H.261 | 0, 1, 3, 5 | 0, 1, 2 . . . 12 |
| H.263 | 0, 1, 2 . . . 8 | 0, 1 . . . 16, 17 |

The GA 250 recognizes the missing GOBs by finding, the GOBs missing in the sequence. Thus:

a. For H.261 and QCIF, if j=0 and k=5, then the repaired packet would include GOBs 1 and 3.

b. For H.261 and CIF, if j=4 and k=0, then the repaired packet would include GOBs 5,6,7 . . . 12.

c. For H.263 and QCIF, if j=6 and k=2, there are 2 packets that need to be repaired. The first packet includes GOBs 7 and 8, and the second packet includes GOBs 0 and 1. A packet is not allowed to include GOBs from different frames.

d. For H.263 and CIF, if j=17 and k=6, the repair packet includes GOBs 0, 1, 2 . . . 5.

e. For H.261 and CIF, if j=4 and k=5 no repaired packet is needed.

If a GOB ID Number is not found in the current packet, no analysis can be performed and the GA 250 drops the current packet. Subsequently, the process returns to step 300 and waits for the next packet.

The GA 250 transfers the results of its analysis (i.e., the missing GOB ID Number) to logical unit PR 260 (FIG. 2), which in turn prepares the necessary repaired packet or packets in step 370.

The packet repair is done based on the compression standard, and the source format, each packet includes the necessary bits plus some extra bits or “stuffing” that keep the continuity of the stream as required by the protocol in use. For example H.261 requires just the GOB headers with no byte alignment, while H.263 requires 1 bit for each non-coded Macro Block (MB). Since H.263 CIF GOB includes 22 MBs, 22 bits of ‘1’ are needed. H.263 QCIF GOB includes only 11 MBs, so in this case 11 bits of ‘1’ are needed. These bits are added to the GOB header. Further, the H.263 frame should be byte aligned, which is guaranteed by the H.263 stuffing.

The PR 260 sends the repaired packet or packets with the current packet as a corrected video stream to the backplane in step 390, and sends an update request to the video source in step 380. Conversely, if the PR 260 does not get a missing packet indication from the PA 220, the PR 260 sends the current packet, as is, to buffer 271. The update request might be a VUPI request, however it is not always necessary. Alternatively, in H.263 a message “VideoNotDecodedMb” may be used and only the missing GOBs/MBs may be updated.

The MPRU 210 can be implemented by software (e.g., an additional software package loaded to an existing processor, such as RTP processor 120). Alternatively, the MPRU 210 may be an additional processor including programs or special hardware for all three units, the PA 220, the GA 250 and the PR 260, or three separate processors, one per unit or any combination of one to three processors and/or hardware units. Memories 230, 240 and TPM 265 (FIG. 2) can be implemented by any one of, or any combination of, SRAM, DRAM, SDRAM, internal and/or external memory.

Although the above exemplary embodiments are given in terms of streams, packets, GOBs, and Slices, the invention can be applied to video streams that are divided into other units, parts, and/or sub-units. Similarly, the missing packet repair unit, MPRU 210, is just an example of a missing part repair unit.

As can be understood from the above description, the present system improves traffic over a network by replacing missing GOBs/Slices, and thereby enhances the continuity of data streams at a receiver side. The continuity of the data stream enables smooth parsing (without synchronization losses and re-synchronization process) by video “decoders” and improves the quality of video communication. In the description and claims of the present application, each of the verbs, “comprise” “include” and “have”, and conjugates thereof, are used to indicate that the object or objects of the verb are not necessarily a complete listing of members, components, elements or parts of the subject or subjects of the verb.

While the invention has been described with reference to specific embodiments, it will be understood by those skilled in the art that various changes may be made and equivalents may be substituted for elements thereof without departing from the true spirit and scope of the invention. In addition, modifications may be made without departing from the essential teachings of the invention.

What is claimed

1. An apparatus for facilitating multimedia communication between a plurality of endpoints over a packet based network, each respective endpoint sending a compressed video output signal and receiving a compressed video input signal, having at least one network interface to a packet-based network, the network interface comprising:
a missing packets repair logical unit, said missing packets repair logical unit handling missing packets and thereby maintaining continuity of a video stream and reducing traffic over said network.

2. The network interface of claim 1, wherein the missing packets repair logical unit further comprises:
a first analyzer that analyzes if a packet is missing;
a second analyzer that analyzes which Group Of Blocks (GOBs) are in the missing packet; and
a repair unit that replaces the missing packets.

3. The apparatus of claim 1 wherein the network is a local area network.

4. The apparatus of claim 1 wherein the network is a wide area network.

5. The apparatus of claim 1 wherein the video stream is repaired during a video stream receiving.

6. A system comprising:
a network interface unit having
a video stream repair unit that receives a video stream from a real time protocol unit, having
a detector unit that detects missing packets,
an analyzer unit that analyzes which video parts are missing,
a replacement unit that receives an indication from the detector unit that packets are missing, and
information from the analyzer unit, the information including which video parts are missing, and in response to receiving the indication and the information replaces a missing packets in a video stream during transmission of the video stream over a network as part of a receive process.

7. A method for repairing missing packets in video communication over a packet-based network, the method comprising:
analyzing if at least one packet is missing;
determining which Group of Blocks (GOBs) are missing;
preparing new packets which will replace the GOBs; and
sending the new packets to a destination.

8. The method of claim 7 wherein the destination is a point remote from where the analyzing occurs.

9. A method comprising:
transmitting a video session over a network; and
replacing a missing part from the video session while the video session is being transmitted.

10. The method of claim 9 wherein the missing part is replaced in an intermediate node during a receiving process that receives the video session.

11. The method of claim 10 further comprising detecting the missing part during the receiving process.

12. The method of claim 11 wherein detecting the missing part includes detecting if a part of the video session received is out of sequence

13. The method of claim 9 wherein replacing the missing part is dependent on the frame type.

14. The method of claim 12 wherein:
each part of a video session has an ID number; and
analyzing which part is missing comprises
finding the ID number of the last received video session part, and
finding the ID number of a first video session part of a stream currently being analyzed.

15. The method of claim 9 wherein the missing part is at least one GOB.

16. A computer usable storage medium having stored thereon a method comprising:
transmitting a video session over a network; and
replacing a missing part from the video session while the video session is being transmitted.

17. The computer usable storage medium of claim 16 wherein the missing part is replaced in an intermediate node during a receiving process that receives the video session.

18. The computer usable storage medium of claim 17, the method further comprising detecting the missing part during the receiving process.

19. The computer usable storage medium of claim 18 wherein detecting the missing part includes detecting if a part of the video session received is out of sequence

20. The computer usable storage medium of claim 16 wherein replacing the missing part is dependant on a frame type.

21. The computer usable storage medium of claim 19 wherein:
each part of a video session has an ID number; and
analyzing which part is missing comprises;
finding the ID number of the last received video session part, and
finding the ID number of a first video session part of a stream currently being analyzed.

22. The computer usable medium of claim 16 wherein the missing part is a packet.

23. The network interface of claim 1, wherein the missing packets repair logical unit further comprises:
a first analyzer that analyzes if a packet is missing;
a second analyzer that analyzes which Slices are in the missing packet; and
a repair unit that replaces the missing packets.

24. A method for repairing missing packets in video communication over a packet-based network, the method comprising:
analyzing if at least one packet is missing;
determining which Slices are missing;
preparing new packets which will replace the Slices; and
sending the new packets to a destination.

25. The method of claim 9 wherein the missing part is at least one Slice.
